(19) United States
(12) Patent Application Publication
(10) Pub. No.: US 2026/0064899 A1
(43) Pub. Date: Mar. 5, 2026

(54) AUDIO-BASED STRUCTURAL REMODEL PLAN GENERATION

(71) Applicant: CoreLogic Solutions, LLC, Irvine, CA (US)

(72) Inventor: Ryan William Golding, Orem, UT (US)

(21) Appl. No.: 19/309,229

(22) Filed: Aug. 25, 2025

Related U.S. Application Data
(60) Provisional application No. 63/688,025, filed on Aug. 28, 2024.
(60) Provisional application No. 63/688,102, filed on Aug. 28, 2024.

(51) Int. Cl. G06F 30/13; G06F 30/12; G06F 30/27; G10L 15/183; G10L 15/22; G10L 25/57

(52) U.S. Cl. CPC G06F 30/13; G06F 30/12; G06F 30/27; G10L 15/183; G10L 15/22; G10L 25/57

(57) ABSTRACT

An artificial intelligence-based structural remodel estimation system is described herein that processes audio taken of a walkthrough of the structure, processes floor plans, and uses large language models to generate a remodel plan that identifies features of a structure to replace, that is more objective than humans, and that is more accurate than remodel plans generated solely based on structural images. For example, the remodel plan may identify features of a structure to replace and/or materials that may be involved in completing a feature replacement. The artificial intelligence-based structural remodel estimation system can use an audio-based approach to generate the remodel plan.

### CROSS-REFERENCE TO RELATED APPLICATIONS

This application claims priority to U.S. Provisional Ser. No. 63/688,025, entitled “ARTIFICIAL INTELLIGENCE-BASED STRUCTURAL REMODEL PLAN GENERATION” and filed on Aug. 28, 2024, and to U.S. Provisional Ser. No. 63/688,102, entitled “AUDIO-BASED STRUCTURAL REMODEL PLAN GENERATION” and filed on Aug. 28, 2024, each of which is hereby incorporated by reference herein in its entirety.

### BACKGROUND

Structures that reside on parcels—such as houses, office buildings, commercial buildings, and/or the like—may degrade over time or become damaged due to weather events, human actions, and/or the like. For example, a structure may include various features, such as flooring, appliances, drywall, windows, and/or the like. As individuals use a structure for various purposes, the features of the structure may begin to wear, become damaged, or otherwise show signs of needing replacement. It can be difficult, however, to identify specifically what type of work would need to be completed to remedy structural feature degradation.

### SUMMARY

The systems, methods, and devices described herein each have several aspects, no single one of which is solely responsible for its desirable attributes. Without limiting the scope of this disclosure, several non-limiting features will now be discussed briefly.

One aspect of the disclosure provides a system comprising memory that stores computer-executable instructions. The system further comprises a processor in communication with the memory, wherein the computer-executable instructions, when executed by the processor, cause the processor to: obtain a request to generate a remodel plan for a room in a structure, wherein the request comprises a description of remodel work to perform and a floor plan of the structure; generate a prompt based on the description of the remodel work to perform, wherein the prompt identifies the room in the structure and includes a copy of the floor plan; provide the prompt as an input to a large language model, wherein providing the prompt as the input to the large language model causes the large language model to output an action and a material; determine an item that is associated with the material; and generate the remodel plan, wherein the remodel plan includes an identification of the action, the material, and the item.

The system of the preceding paragraph can include any sub-combination of the following features: where the computer-executable instructions, when executed, further cause the processor to: cause a user device to display a user interface that depicts the remodel plan, and obtain user feedback on the remodel plan; where the computer-executable instructions, when executed, further cause the processor to modify the user interface to reflect a modification to the remodel plan indicated in the user feedback; where the computer-executable instructions, when executed, further cause the processor to cause the large language model to be re-trained based on the user feedback; where the user feedback comprises an indication of a change to the remodel plan; where the material output by the large language model is to be used in performing the action output by the large language model; where the remodel plan further includes an identification of an amount of the material and an amount of the item involved in completing the action; and where the system further comprises a data store that includes an association of the material with the item, wherein the computer-executable instructions, when executed, further cause the processor to query the data store using an identification of the material to determine the item that is associated with the material.

Another aspect of the disclosure provides a computer-implemented method comprising: obtaining a request to generate a remodel plan for a room in a structure, wherein the request comprises a description of remodel work to perform and a floor plan of the structure; generating a prompt based on the description of the remodel work to perform, wherein the prompt identifies the room in the structure and includes a copy of the floor plan; providing the prompt as an input to a large language model, wherein providing the prompt as the input to the large language model causes the large language model to output an action and a material; determining an item that is associated with the material; and generating the remodel plan, wherein the remodel plan includes an identification of the action, the material, and the item.

The computer-implemented method of the preceding paragraph can include any sub-combination of the following features: where the computer-implemented method further comprises causing a user device to display a user interface that depicts the remodel plan, and obtaining user feedback on the remodel plan; where the computer-implemented method further comprises modifying the user interface to reflect a modification to the remodel plan indicated in the user feedback; where the computer-implemented method further comprises causing the large language model to be re-trained based on the user feedback; where the user feedback comprises an indication of a change to the remodel plan; where the material output by the large language model is to be used in performing the action output by the large language model; and where the remodel plan further includes an identification of an amount of the material and an amount of the item involved in completing the action.

Another aspect of the disclosure provides a non-transitory, computer-readable medium comprising computer-executable instructions for generating a remodel plan, wherein the computer-executable instructions, when executed by a computer system, cause the computer system to: obtain a request to generate a remodel plan for a room in a structure, wherein the request comprises a description of remodel work to perform and a floor plan of the structure; generate a prompt based on the description of the remodel work to perform, wherein the prompt identifies the room in the structure and includes a copy of the floor plan; provide the prompt as an input to a large language model, wherein providing the prompt as the input to the large language model causes the large language model to output an action and a material; determine an item that is associated with the material; and generate the remodel plan, wherein the remodel plan includes an identification of the action, the material, and the item.

The non-transitory, computer-readable medium of the preceding paragraph can include any sub-combination of the following features: where the computer-executable instructions, when executed, further cause the computing system to: cause a user device to display a user interface that depicts the remodel plan, and obtain user feedback on the remodel plan; where the computer-executable instructions, when executed, further cause the computing system to modify the user interface to reflect a modification to the remodel plan indicated in the user feedback; where the computer-executable instructions, when executed, further cause the computing system to cause the large language model to be re-trained based on the user feedback; and where the user feedback comprises an indication of a change to the remodel plan.

Another aspect of the disclosure provides a system comprising memory that stores computer-executable instructions. The system further comprises a processor in communication with the memory, wherein the computer-executable instructions, when executed by the processor, cause the processor to: obtain audio of a walkthrough of a structure, wherein the audio identifies remodel work to perform in a room of the structure; perform speech recognition on the audio to generate a transcript; extract a portion of the transcript that corresponds with the room of the structure; generate a prompt based on the extracted portion of the transcript, wherein, wherein the prompt identifies the room in the structure and includes a copy of a floor plan of the structure; provide the prompt as an input to a large language model, wherein providing the prompt as the input to the large language model causes the large language model to output an action and a material; determine an item that is associated with the material; and generate a remodel plan, wherein the remodel plan includes an identification of the action, the material, and the item.

The system of the preceding paragraph can include any sub-combination of the following features: where the audio is extracted from a video that captures the walkthrough of the structure; where one or more timestamps of the video are mapped to a particular room of the structure; where the portion of the transcript that corresponds with the room of the structure is a portion of the transcript that is derived from audio of the video that has a first timestamp mapped to the room; where the computer-executable instructions, when executed, further cause the processor to: cause a user device to display a user interface that depicts the remodel plan, and obtain user feedback on the remodel plan; where the computer-executable instructions, when executed, further cause the processor to modify the user interface to reflect a modification to the remodel plan indicated in the user feedback; where the computer-executable instructions, when executed, further cause the processor to cause the large language model to be re-trained based on the user feedback; where the user feedback comprises an indication of a change to the remodel plan; where the material output by the large language model is to be used in performing the action output by the large language model; where the remodel plan further includes an identification of an amount of the material and an amount of the item involved in completing the action; and where the system further comprises a data store that includes an association of the material with the item, wherein the computer-executable instructions, when executed, further cause the processor to query the data store using an identification of the material to determine the item that is associated with the material.

Another aspect of the disclosure provides a computer-implemented method comprising: obtaining audio of a walkthrough of a structure, wherein the audio identifies remodel work to perform in a room of the structure; performing speech recognition on the audio to generate a transcript; extracting a portion of the transcript that corresponds with the room of the structure; generating a prompt based on the extracted portion of the transcript, wherein, wherein the prompt identifies the room in the structure and includes a copy of a floor plan of the structure; providing the prompt as an input to a large language model, wherein providing the prompt as the input to the large language model causes the large language model to output an action and a material; determining an item that is associated with the material; and generating a remodel plan, wherein the remodel plan includes an identification of the action, the material, and the item.

The computer-implemented method of the preceding paragraph can include any sub-combination of the following features: where the audio is extracted from a video that captures the walkthrough of the structure; where one or more timestamps of the video are mapped to a particular room of the structure; where the portion of the transcript that corresponds with the room of the structure is a portion of the transcript that is derived from audio of the video that has a first timestamp mapped to the room; and where the computer-implemented method further comprises causing a user device to display a user interface that depicts the remodel plan, and obtaining user feedback on the remodel plan; where the computer-implemented method further comprises modifying the user interface to reflect a modification to the remodel plan indicated in the user feedback; where the computer-implemented method further comprises causing the large language model to be re-trained based on the user feedback; and where the user feedback comprises an indication of a change to the remodel plan.

Another aspect of the disclosure provides a non-transitory, computer-readable medium comprising computer-executable instructions for generating a remodel plan, wherein the computer-executable instructions, when executed by a computer system, cause the computer system to: obtain audio of a walkthrough of a structure, wherein the audio identifies remodel work to perform in a room of the structure; perform speech recognition on the audio to generate a transcript; extract a portion of the transcript that corresponds with the room of the structure; generate a prompt based on the extracted portion of the transcript, wherein the prompt identifies the room in the structure and includes a copy of a floor plan of the structure; provide the prompt as an input to a large language model, wherein providing the prompt as the input to the large language model causes the large language model to output an action and a material; determine an item that is associated with the material; and generate the remodel plan, wherein the remodel plan includes an identification of the action, the material, and the item.

Another aspect of the disclosure provides a non-transitory, computer-readable medium comprising computer-executable instructions for generating a remodel plan, where the computer-executable instructions, when executed by a computer system, cause the computer system to: generate a prompt based on data that identifies remodel work to perform with respect to a room of a structure, where the prompt identifies the room in the structure and includes a copy of a floor plan of the structure; provide the prompt as an input to a large language model, wherein providing the prompt as the input to the large language model causes the large language model to output an action and a material; determine an item that is associated with the material; and generate the remodel plan, wherein the remodel plan includes an identification of the action, the material, and the item.

The non-transitory, computer-readable medium of the preceding paragraph can include any sub-combination of the following features: where the computer-executable instructions, when executed by the computer system, further cause the computer system to: obtain audio of a walkthrough of the structure, where the audio identifies remodel work to perform in the room of the structure, perform speech recognition on the audio to generate a transcript, extract a portion of the transcript that corresponds with the room of the structure, and generate the prompt based on the extracted portion of the transcript; and where the computer-executable instructions, when executed by the computer system, further cause the computer system to: obtain a request to generate the remodel plan for the room in the structure, where the request comprises a description of remodel work to perform and the floor plan of the structure, and generate the prompt based on the description of the remodel work to perform.

### BRIEF DESCRIPTION OF DRAWINGS

Throughout the drawings, reference numbers may be re-used to indicate correspondence between referenced elements. The drawings are provided to illustrate example embodiments described herein and are not intended to limit the scope of the disclosure.

FIG. 1 is a block diagram of an illustrative operating environment in which an artificial intelligence-based structural remodel estimation system interacts with a large language model service and a remodel data store to generate a remodel plan for a structure.

FIG. 2 is a flow diagram illustrating the operations performed by the components of the operating environment of FIG. 1 to generate a remodel plan.

FIG. 3 is another flow diagram illustrating the operations performed by the components of the operating environment of FIG. 1 to generate a remodel plan.

FIG. 4 is a flow diagram depicting an exemplary remodel plan generation routine illustratively implemented by an artificial intelligence-based structural remodel estimation system, according to one embodiment.

FIG. 5 is another flow diagram depicting an exemplary remodel plan generation routine illustratively implemented by an artificial intelligence-based structural remodel estimation system, according to one embodiment.

### DETAILED DESCRIPTION OF SPECIFIC EMBODIMENTS

As described above, it can be difficult to identify specifically what type of work would need to be completed to remedy the degradation of or damage to features of a structure on a parcel. Conventionally, an individual may walk through a parcel in an attempt to identify features that require replacement. Individuals, however, often make subjective determinations about what features should or should not be replaced. For example, two different individuals may walk through the same structure and come to different conclusions about what features need replacement.

Even if multiple individuals come to the same conclusion about what features need replacement, these individuals may come to different conclusions about what materials or work would need to be completed to properly replace a feature. The subjective nature of humans may therefore lead to the quality of a remodel of a structure being uneven and unpredictable. Ultimately, the unpredictable quality of a remodel of a structure can lead to premature wear or damage to a replaced feature, further wear or damage to features that should have been replaced and were not, wear or damage to a first features that relies on or is adjacent to a second feature that should have been replaced and was not where the first feature otherwise would not have been worn or damaged if the second feature had been replaced, and/or the like.

One approach for overcoming the technical issues described above may be to process images of a structure to determine what features need replacement. For example, a system could obtain static images of a structure or 360 degree images of different rooms in the structure (or images of any angle less than 360 degrees) and process such images to identify wear, damage, or other conditions that may warrant feature replacement. However, simply processing the images themselves may not be sufficient to provide an accurate assessment of wear, damage, or other conditions present therein. For example, the intensity of ambient lighting may be low in a room and therefore it may be difficult to view certain features in the room (and the condition of such features). As another example, the intensity of ambient or artificial lighting may be high in a room and some features of the room may therefore appear washed out in the images. As a result, it may be difficult for a system to accurately identify the condition of the features in the room. As another example, shadows or other obstructions may obscure certain features in a room, and therefore it may be difficult for a system to accurately identify the condition of those features in the room.

Accordingly, described herein is an artificial intelligence-based structural remodel estimation system that processes images of a structure, processes audio taken of a walkthrough of the structure, processes floor plans, and/or uses large language models to generate a remodel plan that identifies features of a structure to replace, that is more objective than humans, and that is more accurate than remodel plans generated solely based on structural images. For example, the remodel plan may identify features of a structure to replace and/or materials that may be involved in completing a feature replacement. The artificial intelligence-based structural remodel estimation system can use one of two approaches to generate the remodel plan.

In a first approach, the artificial intelligence-based structural remodel estimation system may obtain a floor plan of a structure, an identification of a room in the floor plan for which remodeling is intended, and a prompt that identifies one or more features of the room to remodel. The artificial intelligence-based structural remodel estimation system may process the floor plan to generate measurements for the identified room, including a total volume of the identified room, dimensions of the identified room, the total area of walls in the identified room, a perimeter of the floor in the identified room, and/or the like. The prompt can either be a voice prompt or a text prompt. If the prompt is a voice prompt, the artificial intelligence-based structural remodel estimation system can perform speech recognition on the voice prompt to generate a transcript. The artificial intelligence-based structural remodel estimation system can then provide the transcript or the text prompt along with the measurements generated from the floor plan (and/or the floor plan itself and/or an identification of a room in the floor plan) as an input to a large language model. In response, the large language model may output one or more actions and one or more materials associated with each action. In particular, the large language model may identify an action to perform to complete the remodel and a material to be used when performing the action. As an illustrative example, the large language model could output an indication that an action to be performed is “remove and replace” and the material associated with the action is “drywall.”

The artificial intelligence-based structural remodel estimation system can use the material output by the large language model and use a data store to identify whether there are any sub-items associated with the material. For example, an item may be an article that facilitates or aids in the performance of the action with respect to the material or that is otherwise required to perform an action with respect to the material. In other words, an item may be an article that is generally acquired and used when performing an action directed to a specific type of material. As an illustrative example, if the action is “remove and replace” and the material is “drywall,” the data store may identify items “tape” and “mud” associated with “drywall.” Thus, the data store may indicate that “tape” and “mud” are used when removing and replacing drywall.

The artificial intelligence-based structural remodel estimation system can identify the amount of material and/or the amount or number of items that may be needed to perform the action based on the measurements generated from the floor plan. For example, the artificial intelligence-based structural remodel estimation system may obtain measurements of the room that correspond with areas where the material to be removed and/or replaced may be located. As an illustrative example, the artificial intelligence-based structural remodel estimation system can use the measured area of the walls to identify how much drywall, mud, and/or tape may be needed to remodel the remove and replace the existing drywall in the room of the structure.

In a second approach, the artificial intelligence-based structural remodel estimation system may obtain one or more images or a video of a walkthrough of a structure, audio spoken during the walkthrough, and/or a floor plan of the structure. The floor plan may be generated based on the images or video of the walkthrough of the structure. Alternatively, the artificial intelligence-based structural remodel estimation system may obtain the images or video and generate a floor plan of the structure based on the images or video. For example, the artificial intelligence-based structural remodel estimation system may process images or frames of the video to identify walls, edges, or other objects that represent the boundaries of one or more rooms in the structure. The artificial intelligence-based structural remodel estimation system can then generate a floor plan that includes two dimensional lines that represent the location of the boundaries identified in the processed images or frames. Optionally, the artificial intelligence-based structural remodel estimation system may obtain a calibration measurement that indicates an actual dimension of an object located in an image or frame. The artificial intelligence-based structural remodel estimation system can use the calibration measurement to estimate the distance between one end of a wall and another end of a wall, the size of objects in the images or frames, and/or the like.

In some embodiments, the artificial intelligence-based structural remodel estimation system may receive room recognition results that includes metadata identifying what room from the floor plan is being depicted in an image or at a particular timestamp in the video. In other embodiments, the artificial intelligence-based structural remodel estimation system can generate the room recognition results by processing images and/or frames of the video to determine which images and/or frames appear to depict the same objects and/or location (but possibly from different angles). For those images and/or frames that the artificial intelligence-based structural remodel estimation system determines depicts the same object and/or location, the artificial intelligence-based structural remodel estimation system can mark the images as corresponding to a particular room and/or identify the timestamps of the frames and note that those timestamps correspond to a particular room.

The obtained audio spoken during the walkthrough may include utterances indicating what features of a room should be repaired or replaced. Once the audio is obtained, the artificial intelligence-based structural remodel estimation system can perform speech recognition on the audio to generate a transcript. Each portion of the transcript may correspond to a timestamp, and the artificial intelligence-based structural remodel estimation system can therefore associate individual portions of the transcript with a room based on the timestamps. Based on the transcript, the artificial intelligence-based structural remodel estimation system may identify keywords or phrases that were uttered that mention repairing or replacing a feature of a room or noting wear on a feature in a room. The artificial intelligence-based structural remodel estimation system can extract a portion of the transcript that corresponds with a room for which keywords or phrases were identified that mention repairing, replacing, remodeling, etc. a feature within the particular room, and can optionally modify the language of the extracted portion of the transcript to generate a prompt that indicates what feature(s) of the room may require repair, replacement, or otherwise have wear. The artificial intelligence-based structural remodel estimation system may process the floor plan to generate measurements for the particular room, including a total volume of the particular room, dimensions of the particular room, the total area of walls in the particular room, a perimeter of the floor in the particular room, and/or the like. The artificial intelligence-based structural remodel estimation system can then provide the extracted portion of the transcript and/or the prompt along with the measurements generated from the floor plan (and/or the floor plan itself and/or an identification of a room in the floor plan) as an input to a large language model. In response, the large language model may output one or more actions and one or more materials associated with each action. In particular, the large language model may identify an action to perform to complete the remodel and a material to be used when performing the action. As an illustrative example, the large language model could output an indication that an action to be performed is “remove and replace” and the material associated with the action is “drywall.”

The artificial intelligence-based structural remodel estimation system can use the material output by the large language model and use a data store to identify whether there are sub-items associated with the material. For example, an item may be an article that facilitates or aids in the performance of the action with respect to the material or that is otherwise required to perform an action with respect to the material. In other words, an item may be an article that is generally acquired and used when performing an action directed to a specific type of material. As an illustrative example, if the action is “remove and replace” and the material is “drywall,” the data store may identify items “tape” and “mud” associated with “drywall.” Thus, the data store may indicate that “tape” and “mud” are used when removing and replacing drywall.

The artificial intelligence-based structural remodel estimation system can identify the amount of material and/or the amount or number of items that may be needed to perform the action based on the measurements generated from the floor plan. For example, the artificial intelligence-based structural remodel estimation system may obtain measurements of the room that correspond with areas where the material to be removed and/or replaced may be located. As an illustrative example, the artificial intelligence-based structural remodel estimation system can use the measured area of the walls to identify how much drywall, mud, and/or tape may be needed to remodel the remove and replace the existing drywall in the room of the structure.

The artificial intelligence-based structural remodel estimation system can generate a user interface that depicts the action to perform, the material to be used in performing the action, the items to be used in performing the action, and/or the amount and/or cost of the materials and/or items. The depicted information may represent a final remodel plan. In response, a user may provide feedback on the final remodel plan, indicating what actions, materials, items, and/or amounts of materials and/or items, if any, are incorrect, should be canceled, should be modified, or should be added.

The foregoing aspects and many of the attendant advantages of this disclosure will become more readily appreciated as the same become better understood by reference to the following detailed description, when taken in conjunction with the accompanying drawings.

### Example Remodel Estimation Environment

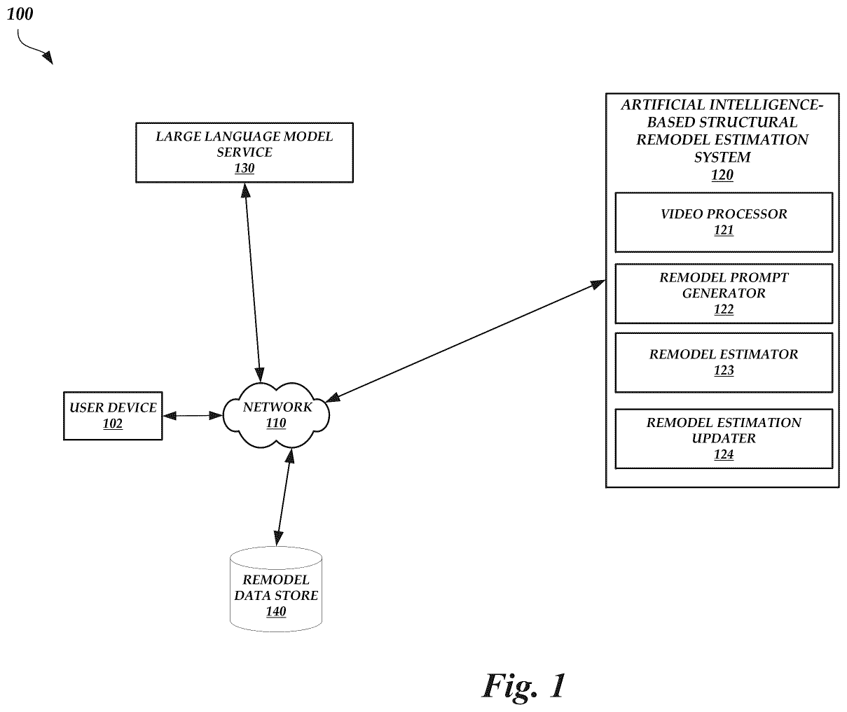

FIG. 1 is a block diagram of an illustrative operating environment 100 in which an artificial intelligence-based structural remodel estimation system 120 interacts with a large language model service 130 and a remodel data store 140 to generate a remodel plan for a structure. The operating environment 100 further includes various user devices 102 that may communicate with the artificial intelligence-based structural remodel estimation system 120 via network 110 to request a remodel plan and/or to provide media (e.g., audio, video, images), floor plans, and/or other related metadata to aid in generation of the remodel plan.

The artificial intelligence-based structural remodel estimation system 120 can be a computing system configured to generate a remodel plan. The artificial intelligence-based structural remodel estimation system 120 may be a single computing device, or it may include multiple distinct computing devices, such as computer servers, logically or physically grouped together to collectively operate as a server system. The components of the artificial intelligence-based structural remodel estimation system 120 can each be implemented in application-specific hardware (e.g., a server computing device with one or more ASICs) such that no software is necessary, or as a combination of hardware and software. In addition, the modules and components of the artificial intelligence-based structural remodel estimation system 120 can be combined on one server computing device or separated individually or into groups on several server computing devices. In some embodiments, the artificial intelligence-based structural remodel estimation system 120 may include additional or fewer components than illustrated in FIG. 1.

In some embodiments, the features and services provided by the artificial intelligence-based structural remodel estimation system 120 may be implemented as web services consumable via the communication network 110. In further embodiments, the artificial intelligence-based structural remodel estimation system 120 is provided by one more virtual machines implemented in a hosted computing environment. The hosted computing environment may include one or more rapidly provisioned and released computing resources, which computing resources may include computing, networking and/or storage devices. A hosted computing environment may also be referred to as a cloud computing environment.

The artificial intelligence-based structural remodel estimation system 120 may include various modules, components, data stores, and/or the like to provide the parcel usage functionality described herein. For example, the artificial intelligence-based structural remodel estimation system 120 may include a video processor 121, a remodel prompt generator 122, a remodel estimator 123, and a remodel estimation updater 124.

As described herein, a remodel plan may identify features of a structure to replace and/or materials that may be involved in completing a feature replacement. The artificial intelligence-based structural remodel estimation system 120 can use one of two approaches to generate the remodel plan.

In a first approach, the remodel prompt generator 122 may obtain a floor plan of a structure, an identification of a room in the floor plan for which remodeling is intended, and a prompt that identifies one or more features of the room to remodel from a user device 102. The remodel prompt generator 122 may process the floor plan to generate measurements for the identified room, including a total volume of the identified room, dimensions of the identified room, the total area of walls in the identified room, a perimeter of the floor in the identified room, and/or the like. The prompt can either be a voice prompt or a text prompt. If the prompt is a voice prompt, the remodel prompt generator 122 can perform speech recognition on the voice prompt to generate a transcript. The remodel prompt generator 122 can then provide the transcript or the text prompt along with the measurements generated from the floor plan (and/or the floor plan itself and/or an identification of a room in the floor plan) as an input to a large language model hosted by the large language model service 130. In response, the large language model hosted by the large language model service 130 may output one or more actions and one or more materials associated with each action. In particular, the large language model may identify an action to perform to complete the remodel and a material to be used when performing the action. As an illustrative example, the large language model could output an indication that an action to be performed is “remove and replace” and the material associated with the action is “drywall.” The large language model service 130 can forward an indication of the action(s) and the material(s) to the remodel estimator 123.

The remodel estimator 123 can use the material output by the large language model and use the remodel data store 140 to identify whether there are any items associated with the material. For example, an item may be an article that facilitates or aids in the performance of the action with respect to the material or that is otherwise required to perform an action with respect to the material. In other words, an item may be an article that is generally acquired and used when performing an action directed to a specific type of material. As an illustrative example, if the action is “remove and replace” and the material is “drywall,” the remodel data store 140 may identify items “tape” and “mud” associated with “drywall.” Thus, the remodel data store 140 may indicate that “tape” and “mud” are used when removing and replacing drywall.

The remodel estimator 123 can identify the amount of material and/or the amount or number of items that may be needed to perform the action based on the measurements generated from the floor plan. For example, the remodel estimator 123 may obtain measurements of the room that correspond with areas where the material to be removed and/or replaced may be located. As an illustrative example, the remodel estimator 123 can use the measured area of the walls to identify how much drywall, mud, and/or tape may be needed to remodel the remove and replace the existing drywall in the room of the structure.

The remodel estimator 123 can then generate a remodel plan that includes an identification of the actions(s), the material(s) and/or item(s) for each action, the amount of material(s) and/or item(s) for each action, and/or the cost of the material(s) and/or item(s) for each action. The remodel estimator 123 can generate a user interface that depicts the remodel plan. The depicted information may represent a final remodel plan. The remodel estimator 123 can provide user interface data to the user device 102 that, when processed by the user device 102, causes the user device 102 to render and display the user interface.

In response to receiving the final remodel plan, a user via user device 102 may provide feedback on the final remodel plan. For example, the user device 102 can transmit to the remodel estimation updater 124 user feedback on the final remodel plan. The user feedback may indicate what actions, materials, items, and/or amounts of materials and/or items, if any, are incorrect, should be canceled, should be modified, or should be added. The remodel estimation updater 124 can use the user feedback to modify the user interface to reflect the user's changes, to provide feedback to the large language model service 130 which can be used by the large language model service 130 to update or re-train the large language model to improve accuracy when processing future prompts, and/or the like.

In a second approach, the video processor 121 may obtain one or more images or a video of a walkthrough of a structure (e.g., 2D image, 360 degree image, 2D video, 360 degree video, etc.), audio spoken during the walkthrough, and/or a floor plan of the structure from a user device 102. The floor plan may be generated based on the images or video of the walkthrough of the structure by a separate system. Alternatively, the video processor 121 may obtain the images or video and generate a floor plan of the structure based on the images or video. For example, the video processor 121 may process images or frames of the video to identify walls, edges, or other objects that represent the boundaries of one or more rooms in the structure. The video processor 121 can then generate a floor plan that includes two dimensional lines that represent the location of the boundaries identified in the processed images or frames. Optionally, the video processor 121 may obtain a calibration measurement that indicates an actual dimension of an object located in an image or frame. The video processor 121 can use the calibration measurement to estimate the distance between one end of a wall and another end of a wall, the size of objects in the images or frames, and/or the like.

In some embodiments, the video processor 121 may receive room recognition results from the user device 102 or separate system that generated by the floor plan that includes metadata identifying what room from the floor plan is being depicted in an image or at a particular timestamp in the video. In other embodiments, the video processor 121 can generate the room recognition results by processing images and/or frames of the video to determine which images and/or frames appear to depict the same objects and/or location (but possibly from different angles). For those images and/or frames that the video processor 121 determines depicts the same object and/or location, the video processor 121 can mark the images as corresponding to a particular room and/or identify the timestamps of the frames and note that those timestamps correspond to a particular room.

The obtained audio spoken during the walkthrough may include utterances indicating what features of a room should be repaired or replaced. Once the audio is obtained, the remodel prompt generator 122 can perform speech recognition on the audio to generate a transcript. Each portion of the transcript may correspond to a timestamp, and the remodel prompt generator 122 can therefore associate individual portions of the transcript with a room based on the timestamps. Based on the transcript, the remodel prompt generator 122 may identify keywords or phrases that were uttered that mention repairing or replacing a feature of a room or noting wear on a feature in a room. The remodel prompt generator 122 can extract a portion of the transcript that corresponds with a room for which keywords or phrases were identified that mention repairing, replacing, remodeling, etc. a feature within the particular room, and can optionally modify the language of the extracted portion of the transcript to generate a prompt that indicates what feature(s) of the room may require repair, replacement, or otherwise have wear. The remodel prompt generator 122 may process the floor plan to generate measurements for the particular room, including a total volume of the particular room, dimensions of the particular room, the total area of walls in the particular room, a perimeter of the floor in the particular room, and/or the like. The remodel prompt generator 122 can then provide the extracted portion of the transcript and/or the prompt along with the measurements generated from the floor plan (and/or the floor plan itself and/or an identification of a room in the floor plan) as an input to a large language model hosted by the large language model service 130. In response, the large language model hosted by the large language model service 130 may output one or more actions and one or more materials associated with each action. In particular, the large language model may identify an action to perform to complete the remodel and a material to be used when performing the action. As an illustrative example, the large language model could output an indication that an action to be performed is “remove and replace” and the material associated with the action is “drywall.” The large language model service 130 can forward an indication of the action(s) and the material(s) to the remodel estimator 123.

The remodel estimator 123 can use the material output by the large language model and query the remodel data store 140 with an identification of the material to identify whether there are any items associated with the material. For example, an item may be an article that facilitates or aids in the performance of the action with respect to the material or that is otherwise required to perform an action with respect to the material. In other words, an item may be an article that is generally acquired and used when performing an action directed to a specific type of material. As an illustrative example, if the action is “remove and replace” and the material is “drywall,” the remodel data store 140 may identify items “tape” and “mud” associated with the query “drywall.” Thus, the remodel data store 140 may indicate that “tape” and “mud” are used when removing and replacing drywall.

The remodel estimator 123 can identify the amount of material and/or the amount or number of items that may be needed to perform the action based on the measurements generated from the floor plan. For example, the remodel estimator 123 may obtain measurements of the room that correspond with areas where the material to be removed and/or replaced may be located. As an illustrative example, the remodel estimator 123 can use the measured area of the walls to identify how much drywall, mud, and/or tape may be needed to remodel the remove and replace the existing drywall in the room of the structure.

The remodel estimator 123 can then generate a remodel plan that includes an identification of the actions(s), the material(s) and/or item(s) for each action, the amount of material(s) and/or item(s) for each action, and/or the cost of the material(s) and/or item(s) for each action. The remodel estimator 123 can generate a user interface that depicts the remodel plan. The depicted information may represent a final remodel plan. The remodel estimator 123 can provide user interface data to the user device 102 that, when processed by the user device 102, causes the user device 102 to render and display the user interface.

In response to receiving the final remodel plan, a user via user device 102 may provide feedback on the final remodel plan. For example, the user device 102 can transmit to the remodel estimation updater 124 user feedback on the final remodel plan. The user feedback may indicate what actions, materials, items, and/or amounts of materials and/or items, if any, are incorrect, should be canceled, should be modified, or should be added. The remodel estimation updater 124 can use the user feedback to modify the user interface to reflect the user's changes, to provide feedback to the large language model service 130 which can be used by the large language model service 130 to update or re-train the large language model to improve accuracy when processing future prompts, and/or the like.

The large language model service 130 may be a computing system that includes one or more hardware processors, one or more graphical processors, memory, and/or other computing resources that are sufficient to host and execute one or more large language models or other machine learning models. The large language model service 130 may be a cloud-based system accessible via the network 110.

The remodel data store 140 may include data entries that associate material(s) with item(s). For example, the remodel data store 140 may include a table that includes an identification of various material(s) and one or more items associated with each respective material. The remodel data store 140 can be a centralized data store or multiple data stores distributed across different geographic locations. While the remodel data store 140 is depicted as being external to the artificial intelligence-based structural remodel estimation system 120, this is not meant to be limiting. For example, the remodel data store 140 can be internal to the artificial intelligence-based structural remodel estimation system 120.

A user device 102 can be any computing device such as a desktop, laptop or tablet computer, personal computer, wearable computer, server, personal digital assistant (PDA), hybrid PDA/mobile phone, mobile phone, electronic book reader, set-top box, voice command device, camera, digital media player, and/or the like. A user device 102 may execute an application or browser that allows a user to request and view a remodel plan generated by the artificial intelligence-based structural remodel estimation system 120, to capture images, audio, and/or video, to generate floor plans, to generate room recognition results, and/or the like.

The network 110 may include any wired network, wireless network, or combination thereof. For example, the network 110 may be a personal area network, local area network, wide area network, over-the-air broadcast network (e.g., for radio or television), cable network, satellite network, cellular telephone network, or combination thereof. As a further example, the network 110 may be a publicly accessible network of linked networks, possibly operated by various distinct parties, such as the Internet. In some embodiments, the network 110 may be a private or semi-private network, such as a corporate or university intranet. The network 110 may include one or more wireless networks, such as a Global System for Mobile Communications (GSM) network, a Code Division Multiple Access (CDMA) network, a Time Division Multiple Access (TDMA) network, an Enhanced Data rates for GSM Evolution (EDGE) network, a Long Term Evolution (LTE) network, a 5G network, a 6G network, or any other type of wireless network. The network 110 can use protocols and components for communicating via the Internet or any of the other aforementioned types of networks. For example, the protocols used by the network 110 may include Hypertext Transfer Protocol (HTTP), HTTP Secure (HTTPS), Message Queue Telemetry Transport (MQTT), Constrained Application Protocol (CoAP), and the like. Protocols and components for communicating via the Internet or any of the other aforementioned types of communication networks are well known to those skilled in the art and, thus, are not described in more detail herein.

### Example Block Diagrams for Generating a Remodel Plan

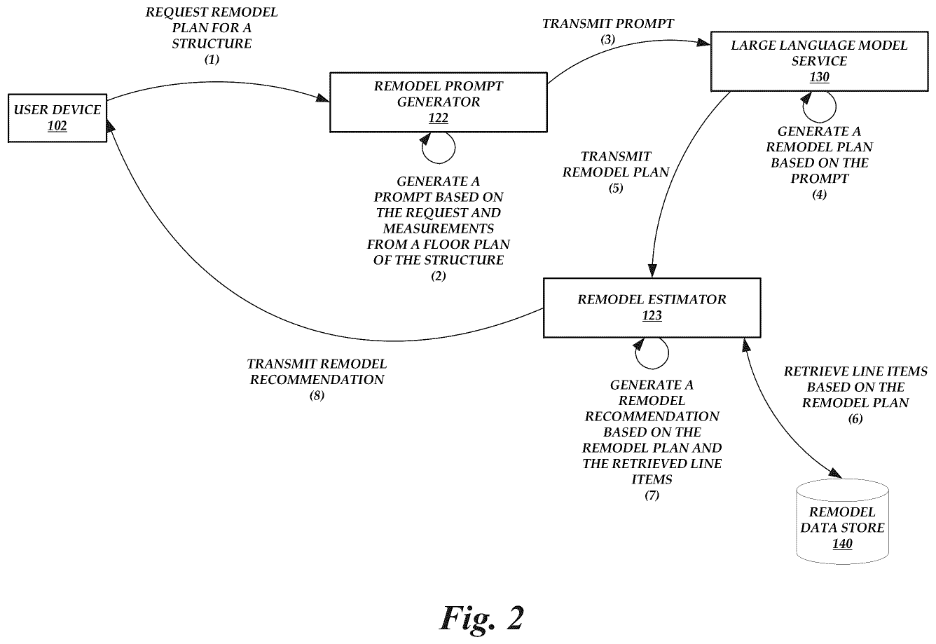

FIG. 2 is a flow diagram illustrating the operations performed by the components of the operating environment 100 of FIG. 1 to generate a remodel plan. As illustrated in FIG. 2, a user device 102 may request a remodel plan for a structure at (1). The request may be transmitted to the remodel prompt generator 122. The request may include a description of the remodeling work to perform, a floor plan of the structure and/or an identification of a room in the structure for which remodeling is desired.

The remodel prompt generator 122 can generate a prompt based on the request and measurements from a floor plan of the structure at (2). For example, the prompt may be text that instructs a large language model to generate a remodel plan to perform the remodeling work described in the description with respect to the identified room in the structure and include a copy of the floor plan. The remodel prompt generator 122 can transmit the prompt to the large language model service 130 at (3).

The large language model service 130 can generate a remodel plan based on the prompt at (4). The remodel plan generated by the large language model service 130 may include one or more actions to perform to complete the remodel and/or one or more material(s) to be used in conjunction with performing each action. The large language model service 130 can transmit the remodel plan to the remodel estimator 123 at (5).

The remodel estimator 123 can retrieve line items from the remodel data store 140 based on the remodel plan at (6). The line items may include item(s) that are associated with each of the material(s) identified in the remodel plan generated by the large language model service 130. The remodel estimator 123 can then generate a remodel recommendation (e.g., a final remodel plan) based on the remodel plan generated by the large language model service 130 and the retrieved line items at (7). For example, the remodel recommendation may include an identification of the actions(s), the material(s) and/or item(s) for each action, the amount of material(s) and/or item(s) for each action, and/or the cost of the material(s) and/or item(s) for each action. The remodel estimator 123 can then transmit the remodel recommendation to the user device 102 at (8) to satisfy the request.

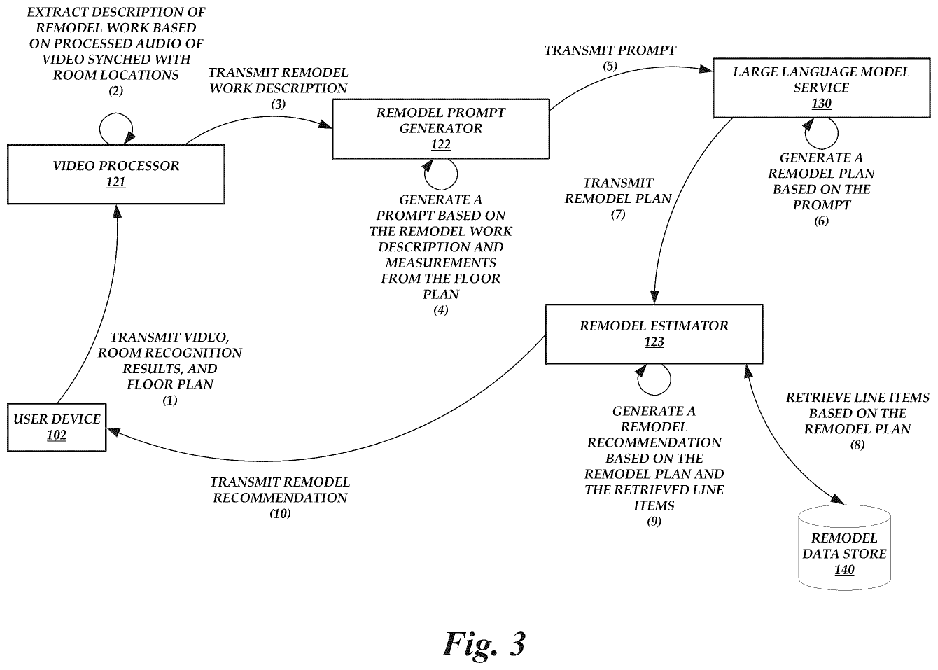

FIG. 3 is another flow diagram illustrating the operations performed by the components of the operating environment 100 of FIG. 1 to generate a remodel plan. As illustrated in FIG. 3, a user device 102 may transmit video (e.g., 2D video, 360 degree video, etc.), room recognition results, and/or a floor plan to the video processor at (1). The video may include audio, and timestamps of the audio may be mapped to specific rooms in the structure captured by the video.

The video processor 121 can extract a description of the remodel work based on processed audio of the video, where the audio is synched with room locations at (2). For example, the audio may be synched or mapped to specific rooms or the location of specific areas of the structure. The video processor 121 can then transmit the remodel work description to the remodel prompt generator 122 at (3).

The remodel prompt generator 122 can generate a prompt based on the remodel work description and measurements from a floor plan of the structure at (4). For example, the prompt may be text that instructs a large language model to generate a remodel plan to perform the remodeling work identified in the description with respect to a particular room in the structure and include a copy of the floor plan. The remodel prompt generator 122 can transmit the prompt to the large language model service 130 at (5).

The large language model service 130 can generate a remodel plan based on the prompt at (6). The remodel plan generated by the large language model service 130 may include one or more actions to perform to complete the remodel and/or one or more material(s) to be used in conjunction with performing each action. The large language model service 130 can transmit the remodel plan to the remodel estimator 123 at (7).

The remodel estimator 123 can retrieve line items from the remodel data store 140 based on the remodel plan at (8). The line items may include item(s) that are associated with each of the material(s) identified in the remodel plan generated by the large language model service 130. The remodel estimator 123 can then generate a remodel recommendation (e.g., a final remodel plan) based on the remodel plan generated by the large language model service 130 and the retrieved line items at (9). For example, the remodel recommendation may include an identification of the actions(s), the material(s) and/or item(s) for each action, the amount of material(s) and/or item(s) for each action, and/or the cost of the material(s) and/or item(s) for each action. The remodel estimator 123 can then transmit the remodel recommendation to the user device 102 at (10) to satisfy the request.

### Example Remodel Plan Generation Routines

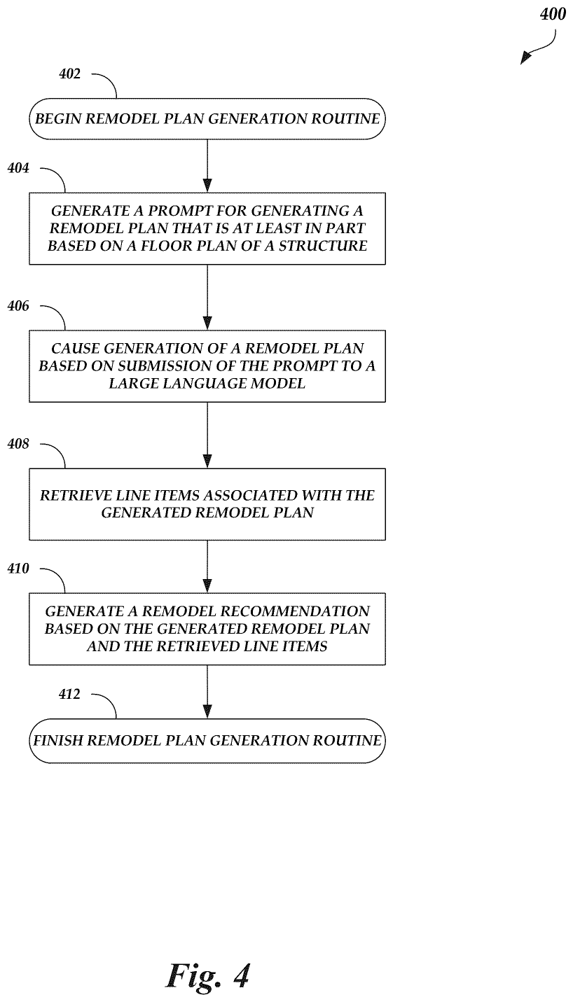

FIG. 4 is a flow diagram depicting an exemplary remodel plan generation routine 400 illustratively implemented by an artificial intelligence-based structural remodel estimation system, according to one embodiment. As an example, the artificial intelligence-based structural remodel estimation system 120 of FIG. 1 can be configured to execute the remodel plan generation routine 400. The remodel plan generation routine 400 begins at block 402.

At block 404, a prompt for generating a remodel plan is generated that is at least in part based on a floor plan of a structure. For example, the prompt may identify remodel work to be performed in a room of the structure and include a copy of the floor plan.

At block 406, generation of a remodel plan is caused based on submission of the prompt to a large language model. For example, the large language model may be running on an external service, such as the large language model service 130. Alternatively, the large language model may be running locally on the artificial intelligence-based structural remodel estimation system. The remodel plan may identify one or more actions to perform and/or one or more materials to be used when completing each action.

At block 408, line items associated with the generated remodel plan are retrieved. For example, the line items may include one or more items that are associated with each material listed in the remodel plan.

At block 410, a remodel recommendation is generated based on the generated remodel plan and the retrieved line items. For example, the remodel recommendation may include an identification of the actions(s), the material(s) and/or item(s) for each action, the amount of material(s) and/or item(s) for each action, and/or the cost of the material(s) and/or item(s) for each action. After the remodel recommendation is generated, the remodel plan generation routine 400 ends, as shown at block 412.

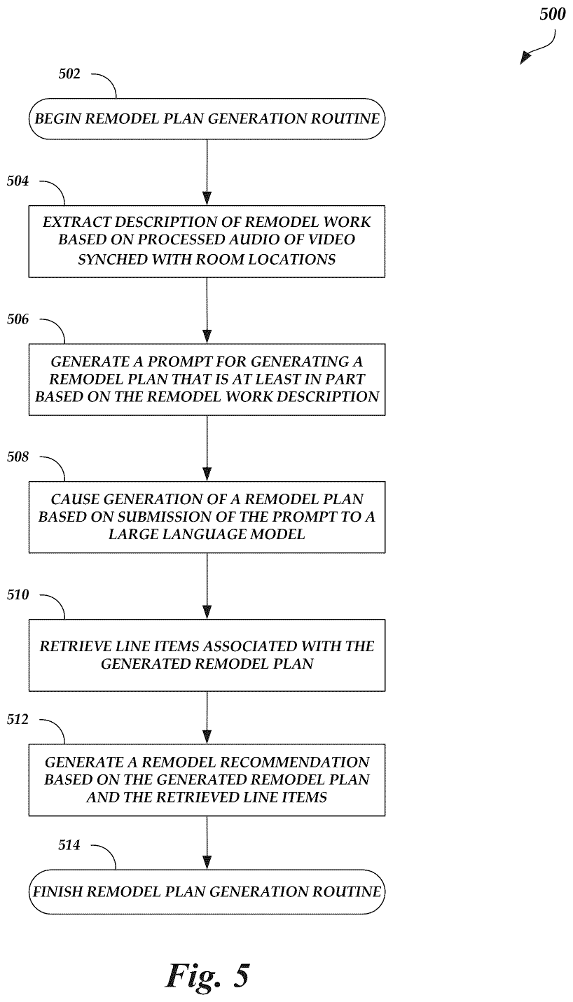

FIG. 5 is another flow diagram depicting an exemplary remodel plan generation routine 500 illustratively implemented by an artificial intelligence-based structural remodel estimation system, according to one embodiment. As an example, the artificial intelligence-based structural remodel estimation system 120 of FIG. 1 can be configured to execute the remodel plan generation routine 500. The remodel plan generation routine 500 begins at block 502.

At block 504, a description of remodel work to be performed is extracted based on processed audio of video synched with room locations. For example, the audio captured during a walkthrough of a structure may describe remodel work to be performed in one or more rooms of the structure. Timestamps of the audio may be synced or mapped to room locations or room identifications, where the timestamps indicate in which room of the structure the audio was recorded.

At block 506, a prompt for generating a remodel plan is generated that is at least in part based on the remodel work description. For example, the prompt may identify remodel work to be performed in a room of the structure based on the description and include a copy of the floor plan.

At block 508, generation of a remodel plan is caused based on submission of the prompt to a large language model. For example, the large language model may be running on an external service, such as the large language model service 130. Alternatively, the large language model may be running locally on the artificial intelligence-based structural remodel estimation system. The remodel plan may identify one or more actions to perform and/or one or more materials to be used when completing each action.

At block 510, line items associated with the generated remodel plan are retrieved. For example, the line items may include one or more items that are associated with each material listed in the remodel plan.

At block 512, a remodel recommendation is generated based on the generated remodel plan and the retrieved line items. For example, the remodel recommendation may include an identification of the actions(s), the material(s) and/or item(s) for each action, the amount of material(s) and/or item(s) for each action, and/or the cost of the material(s) and/or item(s) for each action. After the remodel recommendation is generated, the remodel plan generation routine 500 ends, as shown at block 514.

### Terminology

All of the methods and tasks described herein may be performed and fully automated by a computer system. The computer system may, in some cases, include multiple distinct computers or computing devices (e.g., physical servers, workstations, storage arrays, cloud computing resources, etc.) that communicate and interoperate over a network to perform the described functions. Each such computing device typically includes a processor (or multiple processors) that executes program instructions or modules stored in a memory or other non-transitory computer-readable storage medium or device (e.g., solid state storage devices, disk drives, etc.). The various functions disclosed herein may be embodied in such program instructions, or may be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid state memory chips or magnetic disks, into a different state. In some embodiments, the computer system may be a cloud-based computing system whose processing resources are shared by multiple distinct business entities or other users.

Depending on the embodiment, certain acts, events, or functions of any of the processes or algorithms described herein can be performed in a different sequence, can be added, merged, or left out altogether (e.g., not all described operations or events are necessary for the practice of the algorithm). Moreover, in certain embodiments, operations or events can be performed concurrently, e.g., through multi-threaded processing, interrupt processing, or multiple processors or processor cores or on other parallel architectures, rather than sequentially.

The various illustrative logical blocks, modules, routines, and algorithm steps described in connection with the embodiments disclosed herein can be implemented as electronic hardware (e.g., ASICs or FPGA devices), computer software that runs on computer hardware, or combinations of both. Moreover, the various illustrative logical blocks and modules described in connection with the embodiments disclosed herein can be implemented or performed by a machine, such as a processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor device can be a microprocessor, but in the alternative, the processor device can be a controller, microcontroller, or logic circuitry that implements a state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the rendering techniques described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, routine, or algorithm described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements or steps. Thus, such conditional language is not generally intended to imply that features, elements or steps are in any way required for one or more embodiments or that one or more embodiments necessarily include logic for deciding, with or without other input or prompting, whether these features, elements or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, or Z). Thus, such disjunctive language is not generally intended to, and should not, imply that certain embodiments require at least one of X, at least one of Y, and at least one of Z to each be present.

While the above detailed description has shown, described, and pointed out novel features as applied to various embodiments, it can be understood that various omissions, substitutions, and changes in the form and details of the devices or algorithms illustrated can be made without departing from the spirit of the disclosure. As can be recognized, certain embodiments described herein can be embodied within a form that does not provide all of the features and benefits set forth herein, as some features can be used or practiced separately from others. The scope of certain embodiments disclosed herein is indicated by the appended claims rather than by the foregoing description. All changes which come within the meaning and range of equivalency of the claims are to be embraced within their scope.

What is claimed is:

1. A system comprising:
memory that stores computer-executable instructions; and
a processor in communication with the memory, wherein the computer-executable instructions, when executed by the processor, cause the processor to:
obtain audio of a walkthrough of a structure, wherein the audio identifies remodel work to perform in a room of the structure;
perform speech recognition on the audio to generate a transcript;
extract a portion of the transcript that corresponds with the room of the structure;
generate a prompt based on the extracted portion of the transcript, wherein, wherein the prompt identifies the room in the structure and includes a copy of a floor plan of the structure;
provide the prompt as an input to a large language model, wherein providing the prompt as the input to the large language model causes the large language model to output an action and a material;
determine an item that is associated with the material; and
generate a remodel plan, wherein the remodel plan includes an identification of the action, the material, and the item.

2. The system of claim 1, wherein the audio is extracted from a video that captures the walkthrough of the structure.

3. The system of claim 2, wherein one or more timestamps of the video are mapped to a particular room of the structure.

4. The system of claim 3, wherein the portion of the transcript that corresponds with the room of the structure is a portion of the transcript that is derived from audio of the video that has a first timestamp mapped to the room.

5. The system of claim 1, wherein the computer-executable instructions, when executed, further cause the processor to:
cause a user device to display a user interface that depicts the remodel plan; and
obtain user feedback on the remodel plan.

6. The system of claim 5, wherein the computer-executable instructions, when executed, further cause the processor to modify the user interface to reflect a modification to the remodel plan indicated in the user feedback.

7. The system of claim 5, wherein the computer-executable instructions, when executed, further cause the processor to cause the large language model to be re-trained based on the user feedback.

8. The system of claim 5, wherein the user feedback comprises an indication of a change to the remodel plan.

9. The system of claim 1, wherein the material output by the large language model is to be used in performing the action output by the large language model.

10. The system of claim 1, wherein the remodel plan further includes an identification of an amount of the material and an amount of the item involved in completing the action.

11. The system of claim 1, further comprising a data store that includes an association of the material with the item, wherein the computer-executable instructions, when executed, further cause the processor to query the data store using an identification of the material to determine the item that is associated with the material.

12. A computer-implemented method comprising:
obtaining audio of a walkthrough of a structure, wherein the audio identifies remodel work to perform in a room of the structure;
performing speech recognition on the audio to generate a transcript;
extracting a portion of the transcript that corresponds with the room of the structure;
generating a prompt based on the extracted portion of the transcript, wherein, wherein the prompt identifies the room in the structure and includes a copy of a floor plan of the structure;
providing the prompt as an input to a large language model, wherein providing the prompt as the input to the large language model causes the large language model to output an action and a material;
determining an item that is associated with the material; and
generating a remodel plan, wherein the remodel plan includes an identification of the action, the material, and the item.

13. The computer-implemented method of claim 12, wherein the audio is extracted from a video that captures the walkthrough of the structure.

14. The computer-implemented method of claim 13, wherein one or more timestamps of the video are mapped to a particular room of the structure.

15. The computer-implemented method of claim 13, wherein the portion of the transcript that corresponds with the room of the structure is a portion of the transcript that is derived from audio of the video that has a first timestamp mapped to the room.

16. The computer-implemented method of claim 12, further comprising:
causing a user device to display a user interface that depicts the remodel plan; and
obtaining user feedback on the remodel plan.

17. The computer-implemented method of claim 16, further comprising modifying the user interface to reflect a modification to the remodel plan indicated in the user feedback.

18. The computer-implemented method of claim 16, further comprising causing the large language model to be re-trained based on the user feedback.

19. The computer-implemented method of claim 16, wherein the user feedback comprises an indication of a change to the remodel plan.

20. A non-transitory, computer-readable medium comprising computer-executable instructions for generating a remodel plan, wherein the computer-executable instructions, when executed by a computer system, cause the computer system to:
generate a prompt based on data that identifies remodel work to perform with respect to a room of a structure, wherein the prompt identifies the room in the structure and includes a copy of a floor plan of the structure;
provide the prompt as an input to a large language model, wherein providing the prompt as the input to the large language model causes the large language model to output an action and a material;
determine an item that is associated with the material; and
generate the remodel plan, wherein the remodel plan includes an identification of the action, the material, and the item.

21. The non-transitory, computer-readable medium of claim 20, wherein the computer-executable instructions, when executed by the computer system, further cause the computer system to:
obtain audio of a walkthrough of the structure, wherein the audio identifies remodel work to perform in the room of the structure;
perform speech recognition on the audio to generate a transcript;
extract a portion of the transcript that corresponds with the room of the structure; and
generate the prompt based on the extracted portion of the transcript.

22. The non-transitory, computer-readable medium of claim 20, wherein the computer-executable instructions, when executed by the computer system, further cause the computer system to:
obtain a request to generate the remodel plan for the room in the structure, wherein the request comprises a description of remodel work to perform and the floor
plan of the structure; and
generate the prompt based on the description of the remodel work to perform.
